(19) United States
(12) Patent Application Publication
(10) Pub. No.: US 2024/0355499 A1
(43) Pub. Date: Oct. 24, 2024

(54) SPIRAL GRAPHENE NANOCRYSTAL, GRAPHENE FILM, INTERCONNECTSTRUCTURE, ELECTRONIC DEVICE INCLUDING SAME, AND METHOD OF FABRICATING INTERCONNECT STRUCTURE

(71) Applicants: Samsung Electronics Co., Ltd., Suwon-si (KR); UNIST(ULSAN NATIONAL INSTITUTE OF SCIENCE AND TECHNOLOGY), Ulju-gun (KR)

(72) Inventors: CHANG SEOK LEE, Suwon-si (KR); Yohan KIM, Ulju-gun (KR); Hyung-Joon SHIN, Ulju-gun (KR); KYUNGEUN BYUN, Suwon-si (KR); KEUN WOOK SHIN, Suwon-si (KR); HYEON JIN SHIN, Suwon-si (KR); Seungwoo SON, Ulju-gun (KR); Zonghoon LEE, Ulju-gun (KR)

(21) Appl. No.: 18/641,543

(22) Filed: Apr. 22, 2024

(30) Foreign Application Priority Data
Apr. 20, 2023 (KR) 10-2023-0051844
Aug. 17, 2023 (KR) 10-2023-0107883
Apr. 19, 2024 (KR) 10-2024-0052598

(51) Int. Cl. H01B 1/04; C23C 16/26; C23C 16/50; H01L 21/285; H01L 21/768; H01L 23/48; H01L 23/522; H01L 23/532; H01L 25/065

(52) U.S. Cl. CPC H01B 1/04; H01L 21/76885; H01L 23/481; H01L 23/5226; H01L 23/53276; C23C 16/26; C23C 16/50; H01L 21/28556; H01L 25/0657; H01L 2225/06541; H01L 2225/06565

(57) ABSTRACT

Spiral graphene nanocrystals having electrical conductivity in a vertical direction due to interlayer covalent bonds, a graphene thin film including the spiral graphene nanocrystals, an interconnect structure manufactured from the spiral graphene nanocrystals or the graphene thin film, and a method of manufacturing the interconnect structure and an electronic device including the interconnect structure.

### CROSS REFERENCE TO RELATED APPLICATIONS

This application claims priority to Korean Patent Application No. 10-2023-0051844 filed in the Korean Intellectual Property Office on Apr. 20, 2023, Korean Patent Application No. 10-2023-0107883 filed in the Korean Intellectual Property Office on Aug. 17, 2023, and Korean Patent Application No. 10-2024-0052598 filed in the Korean Intellectual Property Office on Apr. 19, 2024, and all the benefits arising therefrom under 35 U.S.C. § 119, the contents of which are herein incorporated by reference in their entirety.

### BACKGROUND

### 1. Field

A spiral graphene nanocrystal, a graphene thin film including the same, an interconnect structure, an electronic device, and a method of manufacturing an interconnect structure are disclosed.

### 2. Description of the Related Art

There is recent interest in the use of graphene as a promising material in a variety of electronic devices due to the technical advantages obtained by its electrical and chemical characteristics. Graphene can be grown on various substrates by using a chemical vapor deposition (CVD). For example, CVD is a generally known method for growing high-quality graphene on large area substrates. Graphene, however, can be a sensitive structure to certain reaction conditions such as temperature, hydrogen pressure, and the carbon solubility of a substrate.

In order to provide high-density high-performance semiconductor devices, efforts to reduce a width and/or a thickness of a metal wire (or interconnect) are continuously ongoing. If the line width or the thickness of the metal wire line is reduced, the number (or concentration) of semiconductor chips integrated per wafer may be increased, and/or capacitance of the wire line may be reduced resulting in an increase in the speed transmission of a signal through the wire line. However, if the line width or the thickness of the metal wire line is reduced too much, a sharp increase in resistance that may result from an increase in deterioration due to oxidation at the metal/oxide interface or an exposed metal surface. Accordingly, it is desirable to seek and develop new materials for use as a wire line (interconnect) with a reduced structural resistance, which allows for a reduction in deterioration effects due to the oxidation, as well as a material that provides uniformity and relatively fast signal transmission.

### SUMMARY

An embodiment provides a spiral graphene nanocrystal having electrical conductivity in a horizontal direction as well as electrical conductivity in a vertical direction.

Another embodiment provides a graphene thin film having uniform electrical conductivity in both plane direction and thickness direction.

Another embodiment provides an interconnect structure including the spiral graphene nanocrystal having electrical conductivity in a vertical direction.

Another embodiment provides an electronic device including the interconnect structure including the spiral graphene nanocrystal having electrical conductivity in a vertical direction.

Another embodiment provides a method of manufacturing the interconnect structure including the spiral graphene nanocrystal having electrical conductivity in a vertical direction.

A spiral graphene nanocrystal according to an embodiment may have electrical conductivity in a vertical direction due to interlayer covalent bonding.

A spiral graphene nanocrystal according to an embodiment may include a ratio of electrical conductivity in a vertical direction to the electrical conductivity in a horizontal direction of about 1:1 to about 1:100.

A graphene thin film according to another embodiment may include spiral graphene nanocrystals having electrical conductivity in a vertical direction due to interlayer covalent bonding, wherein the spiral graphene nanocrystals are connected to the other in the horizontal direction.

The graphene thin film may have uniform electrical conductivity in a plane direction and uniform electrical conductivity in a thickness direction.

An interconnect structure according to another embodiment may include spiral graphene nanocrystals having electrical conductivity in a vertical direction due to interlayer covalent bonding.

The interconnect structure may have a pillar shape, and at least one end of the pillar shape may be connected to an electrode.

The electrode may include graphene.

The graphene included in the electrode may include spiral graphene nanocrystals having electrical conductivity in a vertical direction due to interlayer covalent bonding.

The electrode may be in a form of a thin film that includes the spiral graphene nanocrystals having electrical conductivity in a vertical direction due to interlayer covalent bonding and connected in the horizontal direction.

The interconnect structure may have one end of the pillar shape that is vertically be connected to a side of the thin film electrode.

An additional interconnect structure may be vertically connected to the one side or an opposite side to the one side of the thin film electrode.

The additional interconnect structure may comprise spiral graphene nanocrystals having electrical conductivity in a vertical direction due to interlayer covalent bonding and may have a member that extends vertically from the thin film electrode.

The additional interconnect structure may further have a member that extends horizontally and connects with the part that extends vertically from the electrode in the form of the thin film.

The additional interconnect structure may further comprise a member that extends vertically and connects with the member that extends horizontally.

The additional interconnect structure may also be connected to a second electrode that is different from the thin film electrode.

The second electrode may comprise spiral graphene nanocrystals having electrical conductivity in a vertical direction due to interlayer covalent bonding.

An interconnect structure according to another embodiment may include a stack, the stack comprises a pillar of a spiral graphene nanocrystal having electrical conductivity in a vertical direction due to interlayer covalent bonding, and an electrode electrically connected to an end (top or bottom end) of the pillar.

The electrode may include a spiral graphene nanocrystal having electrical conductivity in a vertical direction due to interlayer covalent bonding.

A method of manufacturing an interconnect structure according to another embodiment may include patterning a graphene thin film including spiral graphene nanocrystals having electrical conductivity in a vertical direction to a desired shape, wherein the spiral graphene nanocrystals are horizontally connected in the graphene thin film.

Another method of manufacturing an interconnect structure according to embodiment may include growing spiral graphene nanocrystals having electrical conductivity in a vertical direction in a mold using a deposition method.

An electronic device according to another embodiment may include an interconnect structure according to an embodiment.

The electronic device may include a transistor, a capacitor, a diode, or a resistor.

The spiral graphene nanocrystal according to an embodiment may exhibit dominant D and G peaks in a Raman spectrum.

The spiral graphene nanocrystals according to an embodiment may have uniform and relatively fast electrical conductivity in a vertical direction due to interlayer covalent bonding. Accordingly, the spiral graphene nanocrystals can effectively be applied to various interconnect structures that require vertical electrical connection as an alternative to existing (known) graphene thin films. In general, known stacked graphene thin films have little or no electrical conductivity in the vertical direction, that is a ratio of the electrical conductivity in the vertical direction to electrical conductivity in the horizontal direction is about 1:6400. Moreover, the spiral graphene nanocrystals also maintain electrical conductivity in a horizontal direction.

In particular, the spiral graphene nanocrystals according to an embodiment may be used as an effective interconnect material in the semiconductor industry, where vertical chip/device interconnections are increasing due to recent commercial demand or limitations in physical scaling.

Additionally, since graphene has fundamentally excellent electrical and chemical properties, there is no need to worry about problems such as increased resistance due to line width reduction or deterioration due to oxidation of the metal. Furthermore, spiral graphene nanocrystals according to an embodiment can be synthesized relatively quickly on any substrate without catalytic metals present, and thus they have the advantage of quickly growing in situ in a device that requires an interconnect structure.

### BRIEF DESCRIPTION OF THE DRAWINGS

FIG. 1 is a topographic image of a scanning tunneling microscope (STM) of spiral graphene nanocrystals grown on a gold (Au) substrate.

FIG. 2 is an enlarged view of the smaller spiral graphene nanocrystal among those shown in FIG. 1, where b, c, and d show the dl/dV images when the bias voltage is −0.5 V, −0.2 V, and 0.2 V, respectively, at 100 picoamperes (pA).

FIG. 3 is a schematic representation showing the spiral structure of carbon atoms of a spiral graphene nanocrystal according to an embodiment.

FIG. 4 is an STM topographic image showing the Klein-edge structure of spiral graphene nanocrystals.

FIG. 5 is an enlarged view of the rectangular portion in FIG. 4 (FIG. 5b), wherein c of FIG. 5 shows the structure shown in b of FIG. 5 as a ball-stick model, and d of FIG. 5 is a graph showing the height of each edge carbon atom present in b of FIG. 5 and the distance between the carbon atoms, based on the arrow axis indicated by the horizontal dotted line in b of FIG. 5.

FIG. 6 shows dl/dV spectra at the center and edge of the spiral graphene nanocrystal shown in FIG. 4.

FIG. 7 shows FER (Field Emission Resonance) spectra measured at the center and edge of the spiral graphene nanocrystal shown in FIG. 4.

FIG. 8 shows a topographic photograph (a in FIG. 8) showing an enlarged portion of the STM image of the spiral graphene nanocrystals shown in FIG. 1, and a visualization of the lattices of spiral graphene nanocrystals as a dl/dV map.

FIG. 9 is a Fast Fourier Transform (FFT) image of the portion indicated by a rectangle in b of FIG. 8.

FIG. 10 is a schematic view showing an example of applying a spiral graphene nanocrystal to a pillar-shaped interconnect structure according to an embodiment.

FIG. 11 is a schematic view showing an example of a stacked electronic device including a plurality of interconnect structures formed by spiral graphene nanocrystals extending in both vertical and horizontal directions according to an embodiment.

FIG. 12 is a schematic view showing a method of manufacturing an interconnect structure including spiral graphene nanocrystals using a photolithography process according to an embodiment.

### DETAILED DESCRIPTION

Hereinafter, example embodiments will be described in detail so that a person skilled in the art would understand the same. The example embodiments will be described more fully hereinafter with reference to the accompanying drawings, in which various embodiments are shown. This invention may, however, be embodied in many different forms, and should not be construed as limited to the embodiments set forth herein. The terminology used herein is for the purpose of describing particular embodiments only and is not intended to be limiting. As used herein, the singular forms “,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

Herein, it should be understood that terms such as “comprises,” “includes,” or “have” are intended to designate the presence of an embodied feature, number, step, element, or a combination thereof, but does not preclude the possibility of the presence or addition of one or more other features, number, step, element, or a combination thereof.

In the drawings, the thickness of layers, films, panels, regions, etc., are exaggerated for clarity and like reference numerals designate like elements throughout the specification. It will be understood that when an element such as a layer, film, region, or substrate is referred to as being “on” or “above” another element, it may be directly on the other element or intervening elements may also be present. In contrast, when an element is referred to as being “directly on” another element, there are no intervening elements present.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In addition, “layer” herein includes not only a shape formed on the whole surface when viewed from a plan view, but also a shape formed on a partial surface.

The use of the term “the” and similar referential terms may refer to both the singular and the plural. Unless the order of the steps constituting the method is clearly stated or stated to the contrary, these steps may be performed in any appropriate order and are not necessarily limited to the order described.

The connections or connection members of lines between components shown in the drawings exemplify functional connections and/or physical or circuit connections, and in an actual device, they may be represented by a variety of alternative or additional functional, physical, or circuit connections.

As used herein, “at least one of A, B, or C,” “one of A, B, C, or any combination thereof” and “one of A, B, C, and any combination thereof” refer to each constituent element, and any combination thereof (e.g., A; B; C; A and B; A and C; B and C; or A, B, and C).

Herein, “a combination thereof” means a mixture of components, a stack, a composite, an alloy, a blend, and the like.

Hereinafter, unless otherwise defined, “substantially” or “approximately” or “about” means not only the stated value, but also the mean within an acceptable range of deviations, considering the errors associated with the corresponding measurement and the measurement of the measured value. For example, “substantially” or “approximately” can mean within +10%, 5%, 3%, or ±1% or within standard deviation of the stated value, Herein, “metal” is interpreted as a concept that includes metals and metalloids (semi-metals).

Hereinafter, referring to the drawings, a spiral graphene nanocrystal having electrical conductivity in a vertical direction due to interlayer covalent bonding according to an embodiment is described.

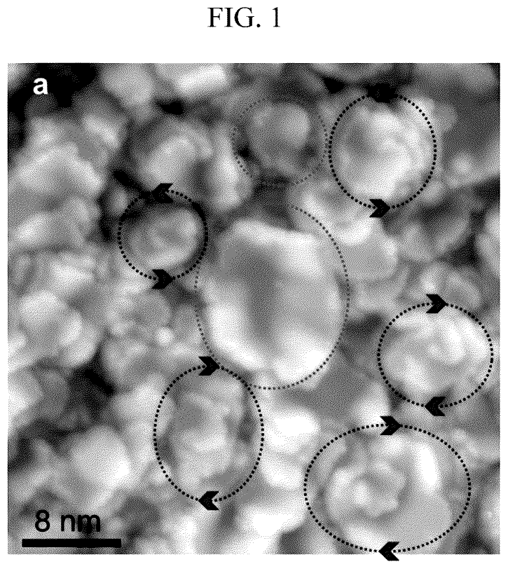

FIG. 1 is a topographic image obtained by a scanning tunneling microscope (STM) showing spiral graphene nanocrystals grown on a gold (Au) substrate according to an example described herein.

In FIG. 1, spiral graphene nanocrystals having electrical conductivity in a vertical direction due to interlayer covalent bonding according to an embodiment are indicated in-part by arrows and dotted circles or ovals. In FIG. 1, the graphene crystals indicated by the dotted circle or oval (without arrows) in the center of the image are stacked graphene crystals in which the spiral graphene nanocrystals are aggregated and piled. The arrow direction (designation) in the circle or oval in FIG. 1 indicates the growth direction of each spiral graphene nanocrystal. That is, as shown in FIG. 1, spiral graphene nanocrystals can grow in a clockwise or counterclockwise direction.

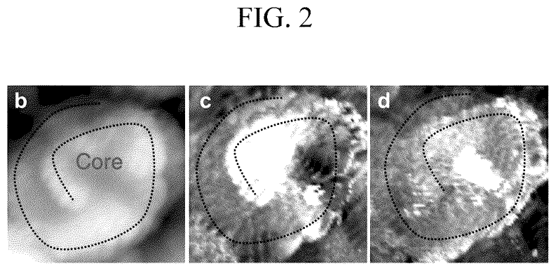

FIG. 2 is an enlarged view of a smaller spiral graphene nanocrystal among those shown in FIG. 1. Herein, (b), (c), and (d) represent dl/dV images when the bias voltage is −0.5V, −0.2V, and 0.2V, respectively, at 100 picoamperes (pA). In the FIG. 2 images, the dotted line in (b), (c), and (d) represents a spiral structure.

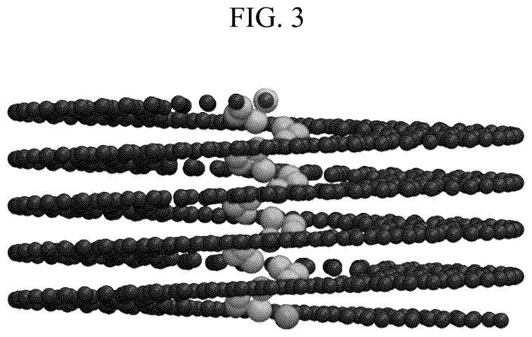

FIG. 3 is a schematic view showing a spiral structure of carbon atoms (black spheres) of a spiral graphene nanocrystal having electrical conductivity in a vertical direction due to interlayer covalent bonding according to an embodiment.

In the case of stacked graphene, shown as the dotted circle or oval of FIG. 1, no covalent bonds are formed between the graphene layers, and only van der Waals interactions exist. The stacked graphene having Van der Waals interactions has an electron-moving speed between layers, that is, electrical conductivity in a vertical direction, which is about 1,000 times lower than the electrical conductivity in a horizontal direction. In other words, multi-layered graphene with a stacking structure has excellent in-plane (horizontal) electrical conductivity, but little or no electrical conductivity in a vertical direction.

On the contrary, the spiral graphene nanocrystal according to an embodiment, as shown in FIG. 3, may significantly improve the electrical conductivity in a vertical direction compared to the stacked graphene due to interlayer covalent bonds between single carbon atoms. Without wishing to be bound by a specific theory, this phenomenon may be thought to be caused by formation of a conductive channel in a core of the spiral graphene nanocrystal. In other words, the spiral graphene nanocrystal may form a faster vertical current pathway as a result of the interlayer covalent bonds of single atoms, and in particular, by a more direct and a shorter current pathway in the core on the spiral nanocrystal. As indicated by the gray spheres in FIG. 3, the core of the spiral graphene nanocrystal may provide a shorter current pathway for electrons to move from the bottom (lower) to the top (upper) or from one end to the other end of the nanocrystal. Accordingly, the spiral graphene nanocrystal according to an embodiment has a ratio of the electrical conductivity in a vertical direction to the electrical conductivity in a horizontal direction within a range of about 1:1 to about 1:100, for example, within a range of about 1:1 to about 1:90, about 1:1 to about 1:80, about 1:1 to about 1:60, or about 1:1 to about 1:40, or about 1:20 to about 1:100, about 1:30 to about 1:100, about 1:50 to about 1:100, or about 1:60 to about 1:100, and thus much improved vertical electrical mobility than stacked graphene. In addition, the spiral graphene nanocrystal according to an embodiment exhibits very uniform vertical electrical conductivity. Accordingly, the spiral graphene nanocrystal according to an embodiment may advantageously be applied as an interconnect material that requires improvement in or an increase in electrical conductivity, and in particular, electrical bonding in a vertical direction.

In addition, in the spiral graphene nanocrystal according to an embodiment, unpaired electrons at the edge of the single carbon atoms as representative of a Klein-edge structure may form a covalent bond with unpaired electrons of carbon atoms at the edge of a neighboring spiral graphene nanocrystal. Accordingly, if a plurality of the spiral graphene nanocrystals are connected in a horizontal direction, the spiral graphene nanocrystals may exhibit uniform electrical conductivity in the horizontal direction as well as in a vertical direction.

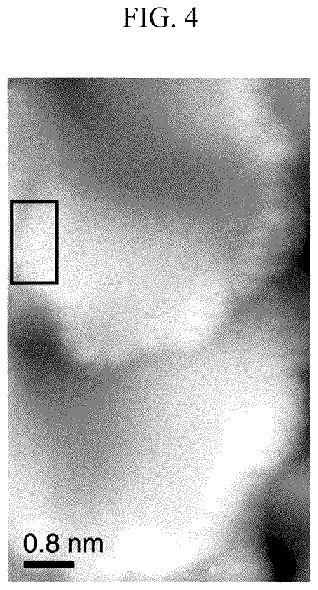

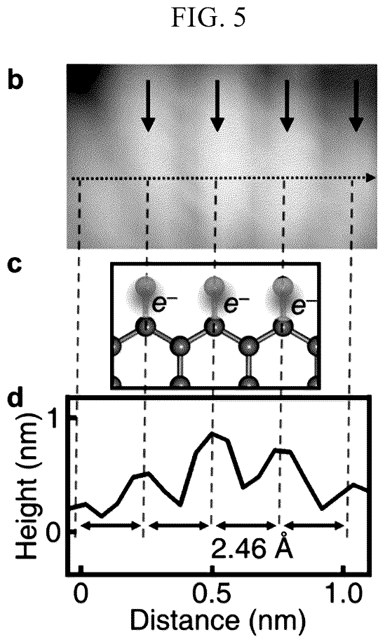

FIG. 4 is an STM topographic image showing the Klein-edge structure of spiral graphene nanocrystals. FIG. 4 is an enlarged view of a partial image of the spiral graphene nanocrystal shown in FIG. 1, and (b) of FIG. 5 is an enlarged view within the rectangular box shown in FIG. 4. In FIG. 5, (c) represents the structure shown in (b) as a ball-stick model. As shown (c) in of FIG. 5, carbon atoms located at the zigzag edges of a hexagonal structure forming graphene have unpaired electrons. In FIG. 5, (d) is a graph showing the spatial heights (distance) of each edge carbon atoms in (b) and the distance between the carbon atoms as indicated by the arrow axis and the horizontal dotted line in FIG. 5.

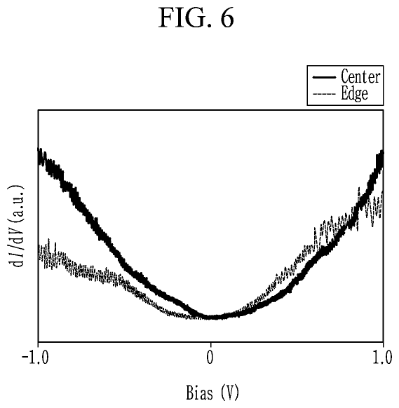

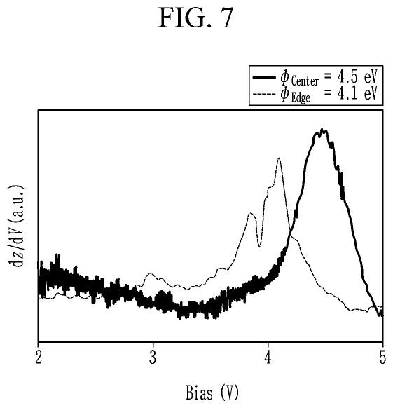

FIG. 6 shows dl/dV spectra at the center and edge of the spiral graphene nanocrystal shown in FIG. 4, and FIG. 7 shows FER (Field Emission Resonance) spectra measured at the center and edge of the spiral graphene nanocrystal. Work function (ϕ, eV) may be obtained from the first FER peaks appearing in the FER spectra.

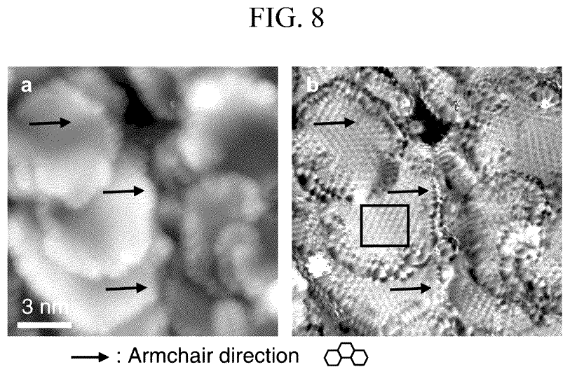

FIG. 8 shows a topographic image (a) showing a more enlarged portion of the STM image of the spiral graphene nanocrystals shown in FIG. 1, and a visualization of the lattices of the spiral graphene nanocrystals as a dl/dV map. As clearly seen from atomic bond shapes inside a rectangle in (b) of FIG. 8, the spiral graphene nanocrystals are very well aligned in an armchair direction, that is, a direction which is marked by the arrows in FIG. 8, in which graphene has a connection structure as indicated as follows,

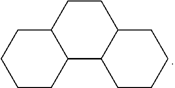 [SMILES: C1CCC2C(C1)CCC1CCCCC12]

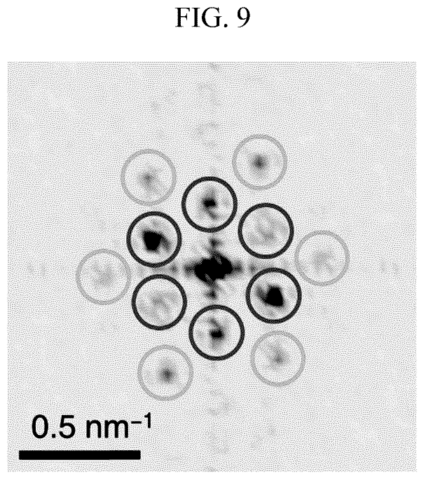

FIG. 9 is a Fast Fourier Transform (FFT) image of a portion marked by the rectangle in (b) of FIG. 8, which confirms that the spiral graphene nanocrystal has very high structural quality through six well-defined graphene reciprocal lattices (R) and a (√3×√3)R30° (R3) supercell. The R3 pattern is largely related to intervalley scattering of delocalized π-electrons in the graphene. Each of the spiral graphene nanocrystals is very well orientated and aligned, and, if ever, has a misorientation of less than about 1.0°. The misorientation of less than about 1.0° is considered to contribute to epitaxial growth of a graphene thin film on the Au (111) surface.

As a result, particles in the same direction nucleate to produce stacked or spiral graphene nanocrystals, which may be identified and classified according to surface topography. Because monocrystalline graphene has been reported to exhibit excellent characteristics, research on synthesizing monocrystalline graphene has been intensively conducted. A thermal chemical vapor deposition (CVD) is most widely used to epitaxially grow graphene on a monocrystalline substrate. However, in contrast to the conventional thermal CVD method, we demonstrate that a ICP-CVD ((Induced Coupled Plasma-CVD) method, which is capable of growing the spiral graphene nanocrystal according to an embodiment, may grow an epitaxial nanocrystal graphene film relatively quickly (at least 10 times or more than the conventional thermal process) on any substrate even in the absence of a metal catalyst and at a lower temperature. This is a very important technical advantage in terms of an application, e.g., the making of an interconnect structure. In conclusion, the spiral graphene nanocrystals according to an embodiment may not only be easily manufactured on any substrate without using a catalyst by ICP-CVD, but also exhibit high quality characteristics, of which an atom structure, electronic characteristics, an edge structure, a crystalline orientation, and the like is demonstrated as evidenced above.

Referring to FIGS. 8 and 9, the spiral graphene nanocrystals possess and maintain uniform electrical conductivity in a vertical direction due to interlayer covalent bonds as well as uniform electrical conductivity in a horizontal direction due to a very well-aligned horizontal connection structure. Moreover, as shown in FIGS. 4 and 5, if spiral graphene nanocrystals are horizontally in contact to each other through the unpaired electrons of carbon on Klein-edges, excellent electrical conductivity in a horizontal direction may be achieved by covalent bonds of the unpaired electrons at the Klien-edges of the spiral graphene nanocrystals. Accordingly, a graphene thin film having uniform electrical conductivity in both the vertical direction and the horizontal directions may be obtained. Moreover, the prepared graphene thin film may then be patterned into a desired shape and applied to various applications for electrical conduction in both the vertical and the horizontal directions. One such application may be exemplified by vertical and/or horizontal interconnect structures.

An interconnect structure including spiral graphene nanocrystals according to an embodiment will be described as follows.

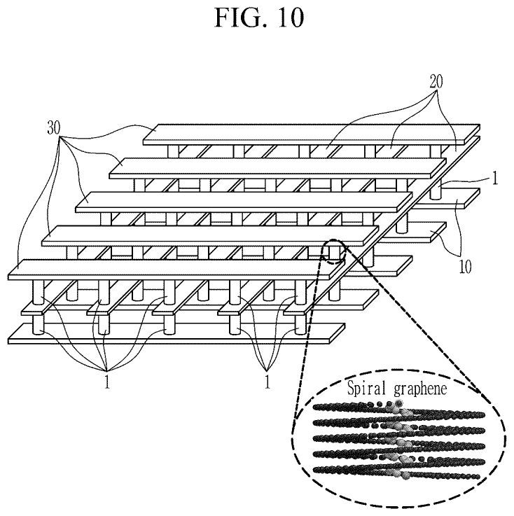

FIG. 10 is a schematic representation of applying spiral graphene nanocrystals to a pillar-shaped interconnect structure according to an embodiment. Referring to FIG. 10, the interconnect structure 1 according to an embodiment is shown in the form of a pillar vertically connecting electrodes 10, 20, and 30, arranged on each layer at regular intervals in horizontal and vertical directions. The spiral structure of the interconnect structure 1 in the form of a pillar is represented by the enlarged oval inset marked by a dotted line, as shown includes the spiral graphene nanocrystals according to an embodiment. The spiral graphene nanocrystals are indicated by schematic atomic bond shapes within the oval inset, and represent the shortest electron movement pathway, as indicated by the lighter gray center spheres positioned in a core portion and in a vertical direction. Accordingly, the interconnect structure 1 including the spiral graphene nanocrystals according to an embodiment may exhibit relatively fast and uniform electrical conductivity in the vertical direction between the electrodes 10, 20, and 30 of each layer.

In an example embodiment, the electrodes 10, 20, and 30 in each layer may be an electrode formed of any material, for example, an electrode including various components such as metals, semi-metals, carbonaceous materials, oxides of the metals, and the like. In another embodiment, but the electrodes 10, 20, and 30 may be electrodes including graphene. Moreover, because graphene is a material that may include the spiral graphene nanocrystal according to an embodiment, the graphene electrode may have little or no contact resistance between the electrode and the interconnect structure. Accordingly, the electrodes 10, 20, and 30 also may include the spiral graphene nanocrystals according to an embodiment.

According to an embodiment, the interconnect structure 1 according to an embodiment and the electrodes 10, 20, and 30 are manufactured of the same material components, and thereby may have little or no contact resistance between them.

Referring to FIG. 10, the interconnect structure 1 is illustrated to be connected to the electrodes 10, 20, and 30 that are disposed at different vertical layers. However, the interconnect structure 1 may be connected to any member requiring electrical connection. For example, the interconnect structure according to an embodiment may be connected to a word line (WL) or a bit line (BL) of a semiconductor device, wherein the word line or bit line may be formed of the spiral graphene nanocrystals according to an embodiment. Accordingly, any contact resistance problem between the interconnect structure and the word line or bit line may be solved.

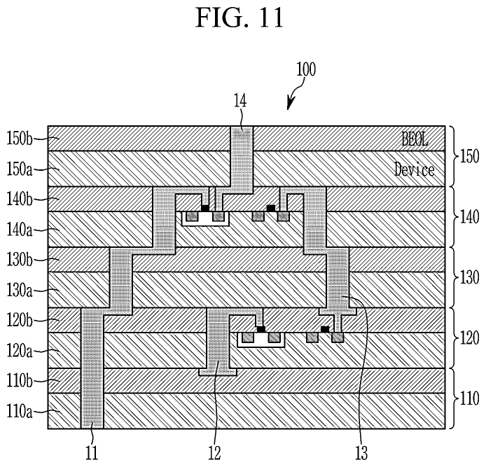

FIG. 11 is a schematic view showing an example of a stacked electronic device including a plurality of interconnect structures formed by spiral graphene nanocrystals extending in both vertical and horizontal directions according to an embodiment. Referring to FIG. 11, the stacked electronic device 100 includes five layers of chips 110, 120, 130, 140, and 150, in which each chip includes devices 110a, 120a, 130a, 140a, and 150a and BEOL (Back End of Line) 110b, 120b, 130b, 140b, and 150b, respectively, for each device. A first interconnect structure 11 including the spiral graphene nanocrystals according to an embodiment penetrates the first layer chip 110 and the second layer chip 120 in a vertical direction, continuously extends from an upper portion of the second layer chip 120 in a horizontal direction, penetrates the third layer chip 130 in the vertical direction, continuously extends from an upper portion of the third layer chip 130 in the horizontal direction, penetrates the fourth layer chip 140 in the vertical direction, continuously extends from an upper portion of the fourth layer chip 140, and then, descends in the vertical direction and is connected to the upper surface of the device 140a under the fourth layer chip 140. In addition, the second interconnect structure 12 is connected to an upper end of the first layer chip 110, extended to the upper end of the second layer chip 120 in a vertical direction, extends therefrom in a horizontal direction, descends therefrom, and is connected to the upper surface of the device 120a under the second layer chip 120. In addition, the third interconnect structure 13 penetrates the third layer chip 130 in the vertical direction from the upper surface of the lower device 120a of the second layer chip 120, extends on the upper surface of the third layer chip 130 in the horizontal direction, penetrates therefrom the fourth layer chip 140 in the vertical direction, extends on the upper surface of the fourth layer chip 140 in the horizontal direction, and descends therefrom in the vertical direction, and is connected to the upper surface of the device 140a under the fourth layer chip 140. Lastly, the fourth interconnect structure 14 descends from the upper surface of the fifth layer chip 150 in the vertical direction, extends on the upper surface of the fourth layer chip 140 in the horizontal direction, descends therefrom in the vertical direction, and is connected to the upper surface of the device 140a under the fourth layer chip 140.

In an electronic device shown in FIG. 11, each interconnect structure 11, 12, 13, and 14 includes the spiral graphene nanocrystals according to an embodiment. As described above, the spiral graphene nanocrystals may have excellent uniform electrical conductivity in the vertical direction by interlayer covalent bonds. In addition, the spiral graphene nanocrystals are also connected in the horizontal direction due to the presence of unpaired electrons of carbon atoms located at the zigzag edges of Klein-edges of the spiral graphene nanocrystals. As a result, neighboring spiral graphene nanocrystals are covalently bonded to the other through the unpaired electrons of carbon atoms, and therefore, horizontally connected on a plane to provide uniform electrical conductivity in the horizontal direction. Furthermore, as shown in the first, second, third, and fourth interconnect structures of FIG. 11, because the interconnect structures include both vertical and horizontal electrical connection and are made of the same material, that is, the spiral graphene nanocrystals, the interconnect structures according to an embodiment have little or no contact resistance in the horizontal and vertical bonds.

Accordingly, the interconnect structure(s) including the spiral graphene nanocrystals according to an embodiment are continuously connected by the same material in the vertical and horizontal directions providing an interconnect structure with little or no contact resistance at both of the vertical and horizontal bonds.

The aforementioned interconnect structure may be manufactured by forming the spiral graphene nanocrystals according to an embodiment into a thin film so that the spiral graphene nanocrystals are included therein are connected in a horizontal direction, patterning the film into a desired shape, or as shown in FIG. 11 of the stacked electronic device 100, by forming a mold in advance according to a shape of the interconnect structure, and directly growing the spiral graphene nanocrystals in the mold.

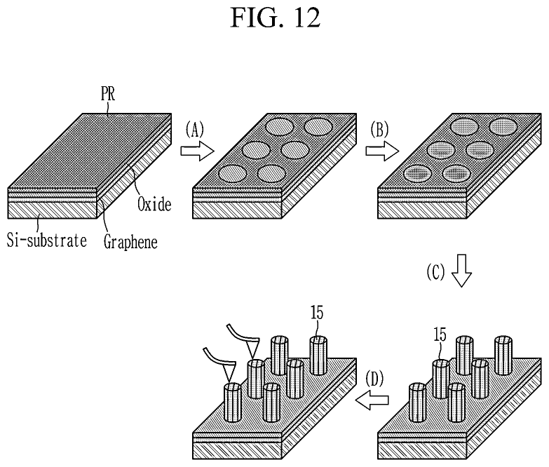

In an embodiment, a method of manufacturing an interconnect structure by patterning a thin film including the spiral graphene nanocrystals connected in the horizontal direction into a desired shape is illustrated in FIG. 12. Referring to FIG. 12, a substrate for an interconnect structure is prepared by sequentially disposing a graphene thin film including the spiral graphene nanocrystals connected in the horizontal direction, an oxide film, and a photoresist (PR) film on a silicon (Si) substrate, for example. Of course, any substrate can be used as described below. A portion of the photoresist film is removed using known methods of photolithography (Step (A)) to form a round photoresist pattern. Subsequently, the oxide exposed through the photoresist pattern is exposed to hydrogen plasma and removed (Step (B)) to expose the spiral graphene nanocrystals of the graphene thin film, which are formed into an interconnect structure consistent with the photoresist pattern. Then, the remaining photoresist (PR) film is removed (Step (C)) through an etching process, obtaining an interconnect structure 15 formed of the spiral graphene nanocrystals extending vertically from the substrate surface covered with the oxide film into a pillar shape. After applying a voltage to the substrate having the interconnect structure 15, the voltage is measured from an upper portion of the interconnect structure 15 to check whether or not the interconnect structure 15 well transmits the voltage applied to the lower substrate (Step (D)).

In another embodiment, the interconnect structure may be manufactured by select placement of a mold on a substrate and then growing the spiral graphene nanocrystals in the mold. Because the spiral graphene nanocrystals according to an embodiment may be deposited on any substrate without a catalyst, etc. in an inductively coupled plasma-chemical vapor deposition (IPC-CVD) method, if the interconnect structure is applied to a semiconductor device, etc., the spiral graphene nanocrystals may directly be grown in-situ on a semiconductor substrate in a mold formed in the device. Accordingly, the spiral graphene nanocrystals according to an embodiment provides a commercial process advantage of being immediately formed in the device through a simple method in a relatively short time.

The substrate on which spiral graphene nanocrystals according to an embodiment may be formed using IPC-CVD may be any substrate, and may include any material selected from, for example, a Group IV semiconductor material, a semiconductor compound (e.g., a Group III-V compound semiconductor, or a Group II-VI compound semiconductor), insulators, and metals. For example, the substrate may include a Group IV semiconductor material such as Si, Ge, or Sn. Alternatively, the substrate may include at least one of Si, Ge, C, Zn, Cd, Al, Ga, In, B, C, N, P, S, Se, As, Sb, Te Ta, Ru, Rh, Ir, Co, Ta, Ti, W, Pt, Au, Ni, and Fe. Also, for example, the substrate may include Si, Ge, SiC, SiGe, SiGeC, Ge alloy, GaAs, InAs, InP, and the like. The substrate may include a single layer or the substrate may have multiple stacked layers of different materials.

In an embodiment, the substrate may include a Silicon-On-Insulator (SOI) substrate, or a Silicon Germanium-On-Insulator (SGOI) substrate. For example, the substrate may be a SiCOH-based composition, may further include N, and/or F, and may include pores in order to lower a dielectric constant. Meanwhile, the substrate may further include a dopant.

The interconnect structure according to an embodiment may be used in an electronic device. For example, the electronic device may include a semiconductor device, and in this case, the interconnect structure can be connected and extended in both vertical and horizontal directions in semiconductor devices that are stacked in one or more layers. Accordingly, if the interconnect structure according to an embodiment is applied for horizontal and/or vertical bonds, there may be little or no contact resistance problem due to the conductivity in both the horizontal and vertical directions. The semiconductor device may include at least one of a transistor, a capacitor, a diode, or a resistor. For example, the interconnect structure according to an embodiment may be connected to a resistive random access memory (RRAM) device in the form of a vertical column, wherein an electrode, a word line (WL), a bit line (BL), and the like are all formed from the spiral graphene nanocrystals, significantly reducing the contact resistance problem.

Hereinafter, a method for manufacturing a spiral graphene nanocrystal according to an embodiment and a method for evaluating its properties will be described in detail through examples.

### Examples

### Preparation of Spiral Graphene Nanocrystals and Thin Films Including the Same.

Spiral graphene nanocrystals are prepared using an inductively coupled plasma-chemical vapor deposition method (ICP-CVD). A substrate is first placed in a CVD chamber at a pressure of 5.0×10⁻⁷ torr, and acetylene (C₂H₂) is used as a carbon source. After increasing the temperature of the substrate under an inert gas flow, the substrate is pretreated with hydrogen (H₂) plasma with an electric power of 150 W at a target temperature to minimize oxygen. In accordance with a target substrate (a Si substrate doped with As⁺² at a high concentration or a monocrystalline gold (Au)/mica substrate) growth conditions spiral graphene nanocrystals are optimized. For example, to produce initial particles (seed crystallites) on the above Si substrate, the Si substrate is heated to 550° C., a gas mixture of C₂H₂:H₂:Ar (2:50:100 sccm) is injected into the chamber at a pressure of 20 Torr, and the plasma is ignited at RF plasma power of 200 W under a pressure of 20 mTorr. In the case of the above Au/mica substrate, the substrate is heated to 400° C., a gas mixture of C₂H₂:H₂:Ar (2:50:100 sccm) is injected into the chamber at a pressure of 20 Torr, and the plasma is ignited with 50 W power at 30 mTorr. Graphene growth time for either substrate is adjusted to a range of 5 minutes to 30 minutes. At the end of the growth period of the spiral graphene nanocrystals, the gas injection and the plasma are stopped, and the chamber is cooled at room temperature under vacuum.

### Evaluation: Characterization of Spiral Graphene Nanocrystals

The grown spiral graphene nanocrystals are examined (analyzed) with respect to the electrical characteristics and microscopic growth by using STM (Scanning Tunneling Microscope: STM), C-AFM (Conductive Atomic Force Microscopy), XPS (X-ray photoelectron spectroscopy), and TEM (Transmission Electron Microscopy). The STM and STS evaluations are performed by using Joule Thomson STM operating at 4.2 K and 3.0×10⁻¹¹ Torr. For a bias voltage, refer to a sample voltage according to a tip. To measure dl/dV and dz/dV spectra, a bias voltage modulation of 50 mV at 727 Hz is used with a lock-in technique. To remove contaminations from the air, a sample of spiral graphene nanocrystals (111) on the Au substrate was cleaned by annealing at 700 K. In the C-AFM measurement, a repulsive interaction force is constantly maintained at 3.35 nN through a feedback loop under the applied bias voltage. A conductive Cr-Ptlr tip (PPP-CONTSCPT, Nanosensors™) is used to obtain two complementary data maps of topographic and conductance maps. The TEM analysis is conducted by using an aberration-corrected transmission electron microscope (Titan G2 Cube 60-300 kV (FEI) at UNIST). To minimize beam irradiation on the samples, a minimal beam exposure approach is applied to collect images at a low operation pressure of 80 kV. The XPS (K-Alpha, Thermo Fisher) is performed to measure chemical compositions of the samples. A C 1s spectrum is fitted by using a minimum set of linear functions including an asymmetric Doniach-Sunjic (DS) function having an asymmetric factor of 0.1 for sp² graphite carbon and a symmetric Gaussian-Lorentzian product function (70% Gaussian and 30% Lorentzian) (GL 30) for other carbon-containing species. A baseline is corrected by using Shirley-type background correction.

The atomic structure of the spiral graphene nanocrystals grown on the Au surface are examined using TEM and STM. Referring to the cross-sections of a TEM image, 5 to 7 multi-layered graphene is formed with a growth time of about 30 minutes, and the growth time is sufficient to cover the surface of the substrate with the nanocrystals. The spiral graphene nanocrystals exhibit dominant D and G peaks in a Raman spectrum, which confirms effective growth on the Au surface.

As seen from the STM topographic image in FIG. 1, the spiral graphene nanocrystals grown on the Au substrate have a particle size of about 10 nm. As shown, two structural types of graphene form on the Au substrate, spiral graphene and stacked graphene. The stacked graphene has strong Van der Waals interactions between layers, and each of the layers is independently grown with respect to the other layers. The spiral layer is a covalently bonded monoatomic layer. Some of the spiral graphene nanocrystal structures exhibit clockwise rotation, while others exhibit counterclockwise rotation. The spiral graphene nanocrystals are formed by screw dislocation and grow through top-growth mechanism in which an upper layer grows atop the lower layer. As shown in FIG. 1, the spiral graphene nanocrystal structures surround the stacked nanocrystal graphene. Without wishing to be bound by a specific theory, the structure is likely governed in-part because the bonding by opposite spiral dislocations is energetically advantageous, wherein the stacked graphene structure may be formed by agglomeration of spiral graphene nanocrystals. The AFM topography also demonstrates spiral morphology of the spiral graphene nanocrystals on the Si substrate.

Although the embodiments have been described in detail above, the scope of rights is not limited thereto, and various modifications and improvements made by those skilled in the art using the basic concepts defined in the following claims also fall within the scope of rights.

What is claimed is:

1. A spiral graphene nanocrystal having electrical conductivity in a vertical direction due to interlayer covalent bonding.

2. The spiral graphene nanocrystal of claim 1, wherein a ratio of the electrical conductivity in a vertical direction to electrical conductivity in the horizontal direction is about 1:1 to about 1:100.

3. A graphene thin film comprising spiral graphene nanocrystals having electrical conductivity in a vertical direction due to interlayer covalent bonding, wherein the spiral graphene nanocrystals are connected in the horizontal direction.

4. The graphene thin film of claim 3, wherein the film has uniform electrical conductivity in a plane direction and uniform electrical conductivity in a thickness direction.

5. An interconnect structure, comprising spiral graphene nanocrystals having electrical conductivity in a vertical direction due to interlayer covalent bonding.

6. The interconnect structure of claim 5, comprising a pillar shape and at least an end of the pillar shape is connected to an electrode.

7. The interconnect structure of claim 6, wherein the electrode comprises graphene.

8. The interconnect structure of claim 7, wherein the graphene of the electrode comprises spiral graphene nanocrystals having electrical conductivity in a vertical direction due to interlayer covalent bonding.

9. The interconnect structure of claim 8, wherein the electrode is a thin film with the spiral graphene nanocrystals connected in the horizontal direction.

10. The interconnect structure of claim 9, wherein the end of the pillar shape is vertically connected to a side of the thin film electrode.

11. The interconnect structure of claim 10, further comprising an additional interconnect structure connected to the one side or an opposite side of the thin film electrode.

12. The interconnect structure of claim 11, wherein the additional interconnect structure comprises spiral graphene nanocrystals having electrical conductivity in a vertical direction due to interlayer covalent bonding, and a member that extends vertically from the thin film electrode.

13. The interconnect structure of claim 12, wherein the additional interconnect structure further comprises a member that extends horizontally and connects with the member that extends vertically from the thin film electrode.

14. The interconnect structure of claim 12, wherein the member that extends vertically connects to a second electrode that is different from the thin film electrode.

15. An interconnect structure comprising a stack, wherein the stack comprises a pillar of a spiral graphene nanocrystal having electrical conductivity in a vertical direction due to interlayer covalent bonding, and an electrode electrically connected to an end of the pillar.

16. The interconnect structure of claim 15, wherein the electrode comprises spiral graphene nanocrystals having electrical conductivity in a vertical direction due to interlayer covalent bonding.

17. A method of manufacturing an interconnect structure, comprising
patterning a graphene thin film comprising spiral graphene nanocrystals having electrical conductivity in a vertical direction, wherein the spiral graphene nanocrystals are horizontally connected in the graphene thin film, or
growing spiral graphene nanocrystals having electrical conductivity in a vertical direction in a mold using a deposition method.

18. An electronic device comprising the interconnect structure of claim 5.

19. The electronic device of claim 18, wherein the electronic device comprises a transistor, a capacitor, a diode, or a resistor.

20. The spiral graphene nanocrystal of claim 1, wherein the nanocrystal exhibit dominant D and G peaks in a Raman spectrum.
